(19) United States
(12) Patent Application Publication
(10) Pub. No.: US 2025/0176337 A1
(43) Pub. Date: May 29, 2025

(54) METHOD OF ALIGNING LIGHT EMITTING ELEMENT AND METHOD OF MANUFACTURING DISPLAY DEVICE

(71) Applicant: Samsung Display Co., LTD., Yongin-si (KR)

(72) Inventor: Joo Nyung JANG, Yongin-si (KR)

(21) Appl. No.: 18/787,666

(22) Filed: Jul. 29, 2024

(30) Foreign Application Priority Data
Nov. 29, 2023 (KR) 10-2023-0169842

(51) Int. Cl. H01L 33/62; H01L 25/16

(52) U.S. Cl. CPC H10H 20/857; H01L 25/167; H10H 20/0364

(57) ABSTRACT

In a method of aligning a light emitting element, the method includes providing a first ink on a substrate on which a first electrode and a second electrode spaced apart from the first electrode are provided, providing a second ink including light emitting elements on the first ink, and applying an AC voltage to the first electrode and the second electrode.

### CROSS-REFERENCE TO RELATED APPLICATION

The present application claims priority to and the benefit of Korean patent application No. 10-2023-0169842, filed on Nov. 29, 2023, in the Korean Intellectual Property Office, the entire content of which is incorporated herein by reference.

### BACKGROUND

### 1. Field

One or more aspects of embodiments of the present disclosure are directed toward a method of aligning a light emitting element and a method of manufacturing a display device, and for example, to a method of aligning a light emitting element on an electrode and a method of manufacturing a display device including the light emitting element.

### 2. Description of the Related Art

As interest in information displays continues to increase, research and development of display devices is being continuously pursued.

A display device is a device which displays images, and includes a display panel such as a light emitting display panel and/or a liquid crystal display panel. The light emitting display panel may be to emit light utilizing a light emitting element, thereby displaying an image. When a Light Emitting Diode (LED) is utilized as the light emitting element, an Organic Light Emitting Diode (OLED) utilizing an organic material as a fluorescent material, an inorganic light emitting diode utilizing an inorganic material as a fluorescent material, and/or the like may be utilized as the light emitting element.

In one or more embodiments, in a manufacturing process of the display device, a plurality of light emitting elements may be arranged between electrodes provided on a substrate. In driving of the display device, light emitting elements arranged in a forward direction may emit light, but light emitting elements arranged in a reverse direction may not emit light. Therefore, it is important (desirable) to align the plurality of light emitting elements in substantially the same direction between the electrodes.

### SUMMARY

One or more aspects of embodiments of the present disclosure are directed toward a method of aligning a light emitting element, which can increase the deflection factor of light emitting elements when the light emitting elements are aligned on an electrode formed on a substrate.

One or more aspects of embodiments of the present disclosure are also directed toward a method of manufacturing a display device, in which a light emitting element is aligned.

In accordance with one or more aspects of embodiments of the present disclosure, there is provided a method of aligning a light emitting element, the method including: providing a first ink on a substrate on which a first electrode and a second electrode spaced from the first electrode are provided; providing a second ink including light emitting elements on the first ink; and applying an AC voltage to the first electrode and the second electrode.

A solvent of the first ink and a solvent of the second ink may be immiscible.

A solvent of the first ink may have a density higher than a density of a solvent of the second ink.

A solvent of the first ink may have a viscosity higher than a viscosity of a solvent of the second ink.

A solvent of the first ink may have a surface tension higher than a surface tension of a solvent of the second ink.

Each of the light emitting elements may include a first conductivity type semiconductor and a second conductivity type semiconductor. The first conductivity type semiconductor of each of the light emitting elements may face in a first electrode direction by applying the AC voltage. The second conductivity type semiconductor of each of the light emitting elements may face in a second electrode direction by applying the AC voltage.

The AC voltage may form a positive dielectrophoresis.

The AC voltage may have an asymmetric waveform.

Each of waveforms of the AC voltage may include at least one selected from among a square wave, a sine wave, a triangle wave, and a sawtooth wave.

In accordance with one or more aspects of embodiments of the present disclosure, there is provided a method of manufacturing a display device, the method including: providing, on a substrate, a first electrode and a second electrode spaced from the first electrode; providing a first ink on the substrate; providing a second ink including light emitting elements on the first ink; and aligning the light emitting elements by applying an AC voltage to the first electrode and the second electrode.

The method may further include allowing the light emitting elements to be settled such that the light emitting elements overlap with an area between the first electrode and the second electrode by applying the AC voltage to the first electrode and the second electrode.

The method may further include allowing the light emitting elements to be settled such that the light emitting elements overlap with an area between the first electrode and the second electrode by applying a DC voltage to the first electrode and the second electrode.

The method may further include volatilizing and removing a solvent of the first ink and a solvent of the second ink.

A solvent of the first ink and a solvent of the second ink may be immiscible.

A solvent of the first ink may have a density higher than a density of a solvent of the second ink.

A solvent of the first ink may have a viscosity higher than a viscosity of a solvent of the second ink.

A solvent of the first ink may have a surface tension higher than a surface tension of a solvent of the second ink.

The AC voltage may form a positive dielectrophoresis.

The AC voltage may have an asymmetric waveform.

Each of waveforms of the AC voltage may include at least one selected from among a square wave, a sine wave, a triangle wave, and a sawtooth wave.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawings, dimensions may be exaggerated for clarity of illustration. It will be understood that when an element is referred to as being “between” two elements, it can be the only element between the two elements, or one or more intervening elements may also be present. Like reference numerals refer to like elements throughout, and duplicative descriptions thereof may not be provided.

FIG. 1 is a perspective view illustrating a light emitting element in accordance with embodiments of the present disclosure.

FIG. 2 is a sectional view illustrating the light emitting element shown in FIG. 1.

FIG. 3 is a plan view illustrating a display device in accordance with embodiments of the present disclosure.

FIG. 4 is a sectional view illustrating a pixel in accordance with embodiments of the present disclosure.

FIG. 5 is a view illustrating in more detail a process in which light emitting elements are aligned on an alignment electrode.

FIG. 6 is a flowchart illustrating a method of manufacturing the display device in accordance with embodiments of the present disclosure.

FIGS. 7-9 are views illustrating an example of a waveform of an AC voltage according to the method shown in FIG. 6.

FIGS. 10-13 are views illustrating in more detail a process in which a light emitting element is aligned according to the method shown in FIG. 6.

FIG. 14 is a view illustrating an example of a substrate on which light emitting elements are aligned according to the method shown in FIG. 6.

FIG. 15 is a flowchart illustrating a method of manufacturing the display device in accordance with embodiments of the present disclosure.

FIG. 16 is a view illustrating an example of a waveform of a voltage applied to a first electrode and a second electrode according to the method shown in FIG. 15.

FIGS. 17 and 18 are views illustrating a kind (or kinds) of dipole moment generated in a light emitting element and a force acting on the light emitting element according the kind of dipole moment.

FIG. 19 is a block diagram illustrating an electronic device in accordance with embodiments of the present disclosure.

FIG. 20 is a view illustrating an example in which the electronic device shown in FIG. 19 is implemented as a smartphone.

### DETAILED DESCRIPTION

Hereinafter, embodiments of the present disclosure will be described in more detail with reference to the accompanying drawings. In the description below, only the parts necessary for (or that assist in) understanding of the present disclosure are described and the descriptions of other parts are omitted (are not provided) in an effort to avoid unnecessarily obscuring subject matter of the present disclosure. The present disclosure is not limited to example embodiments described herein, but may be embodied in one or more suitable different forms. Rather, example embodiments described herein are provided to thoroughly and completely describe the disclosed contents and to sufficiently transfer the ideas of the disclosure to a person of ordinary skill in the art.

In the entire specification, when an element is referred to as being “connected” or “coupled” to another element, it can be directly connected or coupled to the another element (e.g., without any intervening elements therebetween) or be indirectly connected or coupled to the another element with one or more intervening elements interposed therebetween. The technical terms used herein are used only for the purpose of illustrating a specific embodiment and not intended to limit the embodiments. It will be understood that when a component “includes” and/or “comprises” an element, unless there is another (e.g., opposite) description thereto, it should be understood that the component does not exclude another element but may further include another element.

As used herein, expressions such as “at least one of”, “one of”, and “selected from”, when preceding a list of elements, modify the entire list of elements and do not modify the individual elements of the list. It will be understood that for the purposes of this disclosure, “at least one selected from among a, b and c”, “at least one of a, b or c”, and “at least one of X, Y, and/or Z” can be construed as X only, Y only, Z only, or any combination of two or more items X, Y, and/or Z (e.g., XYZ, XYY, YZ, ZZ, etc.). Similarly, for the purposes of this disclosure, “at least one selected from the group consisting of X, Y, and Z” can be construed as X only, Y only, Z only, or any combination of two or more items X, Y, and/or Z (e.g., XYZ, XYY, YZ, ZZ, etc.).

It will be understood that, although the terms “first”, “second,” etc. may be utilized herein to describe one or more suitable elements, these elements should not be limited by these terms. These terms are only utilized to distinguish one element from another element. Thus, a “first” element could also be termed a “second” element without departing from the teachings of the present disclosure.

Spatially relative terms, such as “below,” “above,” and/or the like, may be utilized herein for ease of description to describe the relationship of one element to another element, as illustrated in the drawings. It will be understood that the spatially relative terms, as well as the illustrated configurations, are intended to encompass different orientations of the apparatus in use or operation in addition to the orientations described herein and depicted in the drawings. For example, if the apparatus in the drawings is turned over, elements described as “below” or “beneath” other elements or features would then be oriented “above” the other elements or features. Thus, the example term, “above,” may encompass both (e.g., simultaneously) an orientation of above and below. The apparatus may be otherwise oriented (e.g., rotated 90 degrees or at other orientations) and the spatially relative descriptors utilized herein interpreted accordingly.

As used herein, the singular forms “a,” “an,” and “the” are intended to include the plural forms as well, unless the context clearly indicates otherwise.

As used herein, the terms “use,” “using,” and “used” may be considered synonymous with the terms “utilize,” “utilizing,” and “utilized,” respectively.

As used herein, the term “and/or” includes any and all combinations of one or more of the associated listed items. Further, the use of “may” when describing embodiments of the present disclosure refers to “one or more embodiments of the present disclosure”.

As used herein, the terms “substantially”, “about”, and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The electronic device and/or any other relevant devices or components according to embodiments of the present disclosure described herein may be implemented utilizing any suitable hardware, firmware (e.g. an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

One or more embodiments of the disclosure are described here with reference to schematic diagrams of ideal (or suitable) configurations (and an intermediate structure) of embodiments of the present disclosure, however, changes in a shape as shown due to, for example, manufacturing technology and/or a tolerance may be expected. Therefore, one or more embodiments of the present disclosure shall not be limited to the specific shapes shown in the drawings, but rather shall include shape deviations caused by, for example, the manufacturing technology. The regions shown in the drawings are schematic in nature, and the shapes thereof do not represent the actual shapes of the regions of the device, and do not limit the scope of the disclosure.

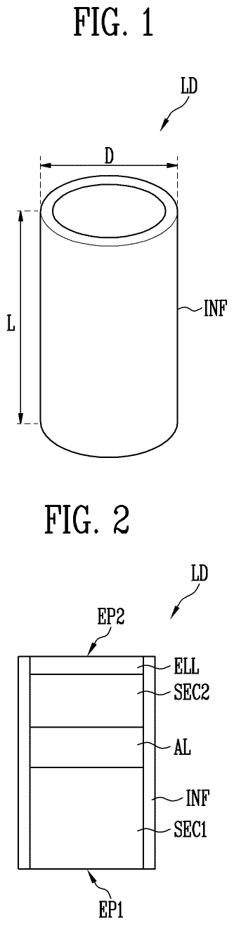

FIG. 1 is a perspective view illustrating a light emitting element in accordance with embodiments of the present disclosure. FIG. 2 is a sectional view illustrating the light emitting element shown in FIG. 1.

Referring to FIGS. 1 and 2, the light emitting element LD may include a first semiconductor layer SEC1, a second semiconductor layer SEC2, and an active layer AL interposed between the first semiconductor layer SEC1 and the second semiconductor layer SEC2. The light emitting element LD may further include an electrode layer ELL. In one or more embodiments, the first semiconductor layer SEC1, the active layer AL, the second semiconductor layer SEC2, and the electrode layer ELL may be sequentially stacked along a length L direction of the light emitting element LD.

The light emitting element LD may have a first end portion EP1 and a second end portion EP2. The first semiconductor layer SEC1 may be adjacent to the first end portion EP1 of the light emitting element LD. The second semiconductor layer SEC2 and/or the electrode layer ELL may be adjacent to the second end portion EP2 of the light emitting element LD.

In one or more embodiments, the light emitting element LD may have a pillar shape. The pillar shape may refer to a shape extending in the length L direction, such as a circular pillar and/or a polygonal pillar. For example, a length L of the light emitting element LD may be greater than a diameter D (or width of a cross-section) of the light emitting element LD. The shape of a section of the light emitting element LD may include a rod-like shape and/or a bar-like shape, but the present disclosure is not limited thereto.

The light emitting element LD may have a size of nanometer scale to micrometer scale. For example, each of the diameter D (or width) and the length L of the light emitting element LD may have a size of nanometer scale to micrometer scale, but the present disclosure is not limited thereto.

The first semiconductor layer SEC1 may be a first conductivity type semiconductor layer. For example, the first semiconductor layer SEC1 may include an N-type semiconductor layer. For example, the first semiconductor layer SEC1 may include any one (e.g., at least one) semiconductor material selected from among InAlGaN, GaN, AlGaN, InGaN, AlN, and InN, and may include an N-type semiconductor layer doped with a first conductivity type dopant such as Si, Ge and/or Sn. However, the material constituting the first semiconductor layer SEC1 is not limited thereto. In one or more embodiments, the first semiconductor layer SEC1 may be configured with one or more suitable materials.

The active layer AL may be arranged on the first semiconductor layer SEC1. The active layer AL may be arranged between the first semiconductor layer SEC1 and the second semiconductor layer SEC2.

The active layer AL may include any one (e.g., at least one) selected from among AlGaInP, AlGaP, AlInGaN, InGaN, and AlGaN. For example, if the active layer AL is to output red light, the active layer Al may include AlGaInP and/or InGaN. For example, if (e.g., when) the active layer AL is to output green light or blue light, the active layer AL may include InGaN. However, the present disclosure is not limited to the above-described example.

The active layer AL may be formed in a single-quantum well structure or a multi-quantum well structure.

The second semiconductor layer SEC2 may be arranged on the active layer AL, and include a semiconductor layer having a conductivity type different from the conductivity type of the first semiconductor layer SEC1. For example, the second semiconductor layer SEC2 may include a P-type semiconductor layer. For example, the second semiconductor layer SEC2 may include at least one semiconductor material selected from among InAlGaN, GaN, AlGaN, InGaN, AlN, and InN, and include a P-type semiconductor layer doped with a second conductivity type dopant such as Mg. However, the material constituting the second semiconductor layer SEC2 is not limited thereto. In one or more embodiments, the second semiconductor layer SEC2 may be configured with one or more suitable materials.

The electrode layer ELL may be formed on the second semiconductor layer SEC2. The electrode layer ELL may include a metal and/or metal oxide. For example, the electrode layer ELL may include at least one selected from among Cr, Ti, Al, Au, Ni, ITO, IZO, ITZO, and oxides and/or alloys thereof.

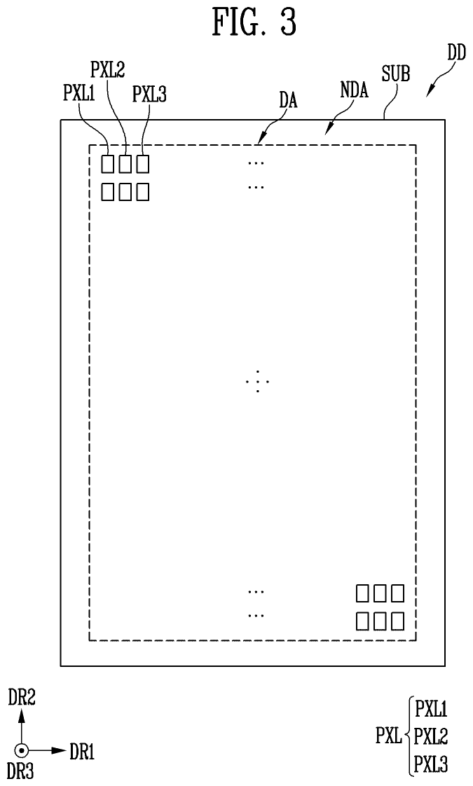

When a voltage which is a threshold voltage or higher is applied to both (e.g., simultaneously) ends of the light emitting element LD, the light emitting element LD may emit light as electron-hole pairs are combined in the active layer AL. The light emission of the light emitting element LD is controlled or selected by utilizing such an aspect, so that the light emitting element LD can be utilized as a light source for one or more suitable light emitting devices, including a pixel of a display device (see e.g., ‘DD’ shown in FIG. 3).

The light emitting element LD may further include an insulative film INF provided on a surface thereof. The insulative film INF may be formed with a single film or a plurality of films.

The insulative film INF may expose both (e.g., simultaneously) end portions of the light emitting element LD, which have different polarities. For example, the insulative film INF may expose a portion of each of the first semiconductor layer SEC1 arranged adjacent to the first end portion EP1 and the electrode layer ELL arranged adjacent to the second end portion EP2.

The insulative film INF may include at least one insulating material selected from among silicon oxide (SiOₓ), silicon nitride (SiNₓ), silicon oxynitride (SiOₓN_{y}), aluminum oxide (AlOₓ), and titanium oxide (TiOₓ). However, the present disclosure is not limited to a specific example.

The insulative layer INF may ensure or improve electrical stability of the light emitting element LD. In one or more embodiments, the occurrence of an unwanted (e.g., undesirable) short-circuit between a plurality of light emitting elements LD may be prevented or reduced, even when the light emitting elements LD are arranged close to each other.

In one or more embodiments, the light emitting element LD may further include an additional component in addition to the first semiconductor layer SEC1, the active layer AL, the second semiconductor layer SEC2, the electrode layer ELL, and the insulative film INF. For example, the light emitting element LD may further include a phosphor layer, an active layer, a semiconductor layer, and/or an electrode layer.

FIG. 3 is a plan view illustrating a display device in accordance with embodiments of the present disclosure.

Referring to FIG. 3, the display device DD is configured to emit light. The display device DD may include a substrate SUB and pixels PXL arranged on the substrate SUB. In some embodiments, the display device DD may further include a driving circuit unit (e.g., a scan driver and/or a data driver) for driving the pixels, lines, and/or pads.

The display device DD may include a display area DA and a non-display area NDA. The non-display NDA may refer to an area except for (e.g., other than) the display area DA. The non-display area NDA may be around (e.g., may surround) at least a portion of the display area DA.

The substrate SUB may constitute a base member of the display device DD. The substrate SUB may be a rigid or flexible substrate and/or film, but the present disclosure is not limited to a specific example.

The display area DA may refer to an area in which the pixels PXL are arranged. The non-display area NDA may refer to an area in which the pixels PXL are not arranged. The driving circuit units, the lines, and/or the pads, which are connected to the pixels PXL of the display area DA, may be arranged in the non-display area NDA.

For example, the pixels PXL may be arranged according to a strip arrangement structure, a PENTILE® arrangement structure (PENTILE® is a registered trademark owned by Samsung Display Co., Ltd.), and/or the like. However, the present disclosure is not limited thereto, and one or more suitable embodiments in the art may be applied.

In one or more embodiments, the pixel PXL may include a first pixel PXL1, a second pixel PXL2, and a third pixel PXL3. Each of the first pixel PXL1, the second pixel PXL2, and the third pixel PXL3 may be a sub-pixel. At least one first pixel PXL1, at least one second pixel PXL2, and at least one third pixel PXL3 may constitute one pixel unit capable of emitting light of one or more suitable colors.

For example, each of the first pixel PXL1, the second pixel PXL2, and the third pixel PXL3 may be to emit light of a set or predetermined color. For example, the first pixel PXL1 may be a red pixel emitting (e.g., configured to emit) light of red (e.g., a first color), the second pixel PXL2 may be a green pixel emitting (e.g., configured to emit) light of green (e.g., a second color), and the third pixel PXL3 may be a blue pixel (e.g., configured to emit) emitting light of blue (e.g., a third color). However, the color, kind, and/or number of first, second, and third pixels PXL1, PXL2, and PXL3 constituting each pixel unit are not limited to a specific example.

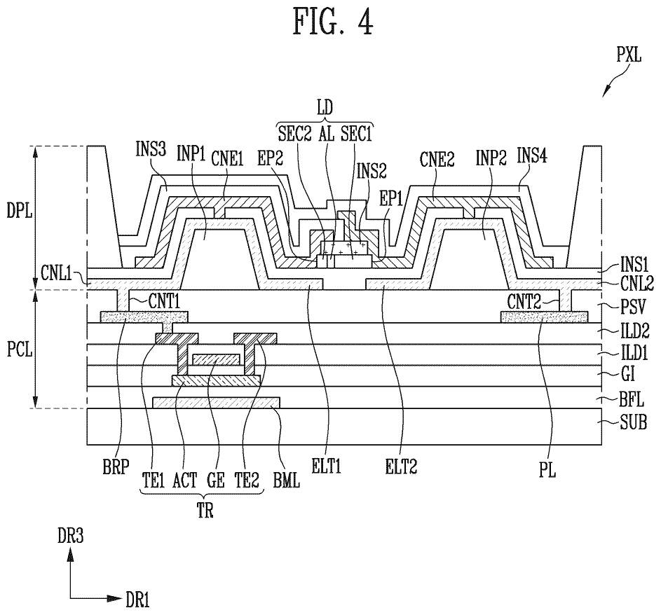

FIG. 4 is a sectional view illustrating a pixel in accordance with embodiments of the present disclosure.

Referring to FIG. 4, the pixel PXL may include a substrate SUB, a pixel circuit layer PCL, and a display element layer DPL.

The substrate SUB may constitute a base member of the display device DD. The substrate SUB may be a rigid or flexible substrate and/or film, but the present disclosure is not limited to a specific example. The substrate SUB may be provided as a base surface, so that the pixel circuit layer PCL and the display element layer DPL are arranged on the substrate SUB.

The pixel circuit layer PCL may be arranged on the substrate SUB. The pixel circuit layer PCL may include a bottom electrode layer BML, a buffer layer BFL, a transistor TR, a gate insulating layer GI, a first interlayer insulating layer ILD1, a second interlayer insulating layer ILD2, a bridge pattern BRP, a power line PL, a protective layer PSV, a first contact portion CNT1, and a second contact portion CNT2.

The bottom electrode layer BML may be arranged on the substrate SUB, to be covered by the buffer layer BFL. A portion of the bottom electrode layer BML may overlap with the transistor TR when viewed on a plane (e.g., in plan view).

In one or more embodiments, the bottom electrode layer BML may include a conductive material, thereby serving as a path through which an electrical signal provided to the pixel circuit layer PCL and the display element layer DPL moves. For example, the bottom electrode layer BML may include any one (e.g., at least one) selected from among aluminum (Al), copper (Cu), titanium (Ti), and molybdenum (Mo).

The buffer layer BFL may be arranged on the substrate SUB. The buffer layer BFL may prevent or reduce diffusion of an impurity from the outside. The buffer layer BFL may include at least one selected from among silicon nitride (SiNₓ), silicon oxide (SiOₓ), silicon oxynitride (SiOₓN_{y}), and a metal oxide such as aluminum oxide (AlOₓ).

The transistor TR may be a thin film transistor. In one or more embodiments, the transistor TR may be a driving transistor.

The transistor TR may be electrically connected (e.g., electrically coupled) to a light emitting element LD. The transistor TR may be electrically connected to the bridge pattern BRP. However, the present disclosure is not limited to the above-described example. For example, the transistor TR may be electrically connected to a first connection electrode CNL1 without passing through the bridge pattern BRP.

The transistor TR may include an active layer ACT, a first transistor electrode TE1, a second transistor electrode TE2, and a gate electrode GE.

The active layer ACT may refer to a semiconductor layer. The active layer ACT may be arranged on the buffer layer BFL. For example, the active layer ACT may include any one (e.g., at least one) selected from among poly-silicon, amorphous silicon, and an oxide semiconductor.

The active layer ACT may include a first contact region in contact with the first transistor electrode TE1 and a second contact region in contact with the second transistor electrode TE2. The first contact region and the second contact region may correspond to a semiconductor pattern doped with an impurity. A region between the first contact region and the second contact region may be a channel region. The channel region may correspond to an intrinsic semiconductor pattern undoped with the impurity.

The gate electrode GE may be arranged on the gate insulating layer GI. A position of the gate electrode GE may correspond to a position of the channel region of the active layer ACT. For example, the gate electrode GE may be arranged on the channel region of the active layer ACT with the gate insulating layer GI interposed therebetween. For example, the gate electrode GE may include any one (e.g., at least one) selected from among aluminum (Al), copper (Cu), titanium (Ti), and molybdenum (Mo).

The gate insulating layer GI may be arranged over the active layer ACT. The gate insulating layer GI may include an inorganic material. For example, the gate insulating layer GI may include at least one selected from among silicon nitride (SiNₓ), silicon oxide (SiOₓ), silicon oxynitride (SiOₓN_{y}), and aluminum oxide (AlOₓ).

The first interlayer insulating layer ILD1 may be located over the gate electrode GE. Like the gate insulating layer GI, the first interlayer insulating layer ILD1 may include at least one selected from among silicon nitride (SiNₓ), silicon oxide (SiOₓ), silicon oxynitride (SiOₓN_{y}), and aluminum oxide (AlOₓ).

The first transistor electrode TE1 and the second transistor electrode TE2 may be located on the first interlayer insulating layer ILD1. The first transistor electrode TE1 may be in contact with the first contact region of the active layer ACT while penetrating the gate insulating layer GI and the first interlayer insulating layer ILD1, and the second transistor electrode TE2 may be in contact with the second contact region of the active layer ACT while penetrating the gate insulating layer GI and the first interlayer insulating layer ILD1. For example, the first transistor electrode TE1 may be a drain electrode, and the second transistor electrode TE2 may be a source electrode. However, the present disclosure is not limited thereto.

The second interlayer insulating layer ILD2 may be located over the first transistor electrode TE1 and the second transistor electrode TE2. Like the first interlayer insulating layer ILD1 and the gate insulating layer GI, the second interlayer insulating layer ILD2 may include an inorganic material. The inorganic material may include at least one of the materials exemplified as the material constituting the first interlayer insulating layer ILD1 and the gate insulating layer GI, e.g., silicon nitride (SiNₓ), silicon oxide (SiOₓ), silicon oxynitride (SiOₓN_{y}), and/or aluminum oxide (AlOₓ).

The bridge pattern BRP may be arranged on the second interlayer insulating layer ILD2. The bridge pattern BRP may be connected to the first transistor electrode TE1 through a contact hole penetrating the second interlayer insulating layer ILD2. The bridge pattern BRP may be electrically connected to a first electrode ELT1 through the first contact portion CNT1 formed in the protective layer PSV.

The power line PL may be arranged on the second interlayer insulating layer ILD2. The power line PL may be electrically connected to a second connection electrode CNL2 through the second contact portion CNT2 formed in the protective layer PSV. The power line PL may provide a power source (or cathode signal) to the light emitting element LD through a second electrode ELT2.

The protective layer PSV may be located on the second interlayer insulating layer ILD2. The protective layer PSV may cover the bridge pattern BRP and the power line PL. The protective layer PSV may be a via layer.

In one or more embodiments, the protective layer PSV may be provided in a form including an organic insulating layer, an inorganic insulating layer, or the organic insulating arranged on the inorganic insulating layer, but the present disclosure is not limited thereto.

In one or more embodiments, the first contact portion CNT1 connected to one area of the bridge pattern BRP and the second contact portion CNT2 connected to one area of the power line PL may be formed in the protective layer PSV.

The display element layer DPL may be arranged on the pixel circuit layer PCL. The display element layer DPL may include a first insulating pattern INP1, a second insulating pattern INP2, the first connection electrode CNL1, the second connection electrode CNL2, a first electrode ELT1, the second electrode ELT2, a first insulating layer INS1, the light emitting element LD, a second insulating layer INS2, a first contact electrode CNE1, a second contact electrode CNE2, a third insulating layer INS3, and a fourth insulating layer INS4.

The first insulating pattern INP1 and the second insulating pattern INP2 may be arranged on the protective layer PSV. The first insulating pattern INP1 and the second insulating pattern INP2 may have a shape protruding in a display direction of the display device DD (e.g., a third direction DR3). For example, the first insulating pattern INP1 and the second insulating pattern INP2 may include an organic material and/or an inorganic material, but the present disclosure is not limited thereto.

The first connection electrode CNL1 and the second connection electrode CNL2 may be arranged on the protective layer PSV. The first connection electrode CNL1 may be connected to the first electrode ELT1. The first connection electrode CNL1 may be electrically connected to the bridge pattern BRP through the first contact portion CNT1. The first connection electrode CNL1 may electrically connect the bridge pattern BRP and the first electrode ELT1 to each other. The second connection electrode CNL2 may be connected to the second electrode ELT2. The second connection electrode CNL2 may be electrically connected to the power line PL through the second contact portion CNT2. The second connection electrode CNL2 may electrically connect the power line PL and the second electrode ELT2 to each other.

The first electrode ELT1 and the second electrode ELT2 may be arranged on the protective layer PSV. In one or more embodiments, at least a portion of the first electrode ELT1 may be arranged over the first insulating pattern INP1 and at least a portion of the second electrode ELT2 may be arranged over the second insulating pattern INP2, to each serve as a reflective partition wall.

The first electrode ELT1 may be electrically connected to the light emitting element LD. The first electrode ELT1 may be electrically connected to the first contact electrode CNE1 through a contact hole formed in the first insulating layer INS1. The first electrode ELT1 may provide an anode signal to the light emitting element LD.

The second electrode ELT2 may be electrically connected to the light emitting element LD. The second electrode ELT2 may be electrically connected to the second contact electrode CNE2 through a contact hole formed in the first insulating layer INS1. The second electrode ELT2 may apply a cathode signal (e.g., a ground signal) to the light emitting element LD.

The first electrode ELT1 and the second electrode ELT2 may include a conductive material. For example, the first electrode ELT1 and the second electrode ELT2 may include metals such as silver (Ag), magnesium (Mg), aluminum (Al), platinum (Pt), palladium (Pd), gold (Au), nickel (Ni), neodymium (Nd), iridium (Ir), chromium (Cr), titanium (Ti), and/or alloys thereof. However, the present disclosure is not limited to the above-described example.

In one or more embodiments, the first electrode ELT1 and the second electrode ELT2 may serve as alignment electrodes for the light emitting element LD. For example, the light emitting element LD may be arranged based on electrical signals provided from the first electrode ELT1 and the second electrode ELT2.

The first insulating layer INS1 may be arranged on the protective layer PSV. The first insulating layer INS1 may cover the first electrode ELT1 and the second electrode ELT2. The first insulating layer INS1 may suitably stabilize connection between electrode components and reduce external influences. The first insulating layer INS1 may include at least one selected from among silicon nitride (SiNₓ), silicon oxide (SiOₓ), silicon oxynitride (SiOₓN_{y}), and aluminum oxide (AlOₓ).

The light emitting element LD may be arranged on the first insulating layer INS1, to emit light, based on electrical signals provided from the first contact electrode CNE1 and the second contact electrode CNE2.

The light emitting element LD may include a first end portion EP1 and a second end portion EP2 as described above with reference to FIGS. 1 and 2.

In one or more embodiments, the first end portion EP1 of the light emitting element LD may be arranged to face the second electrode ELT2 and the second contact electrode CNE2, and the second end portion EP2 of the light emitting element LD may be arranged to face the first electrode ELT1 and the first contact electrode CNE1.

Accordingly, a first semiconductor layer SEC1 of the light emitting element LD may be adjacent to the second electrode ELT2 and the second contact electrode CNE2, and a second semiconductor layer SEC2 of the light emitting element LD may be adjacent to the first electrode ELT1 and the first contact electrode CNE1.

The second insulating layer INS2 may be arranged on the light emitting element LD. The second insulating layer INS2 may cover an active layer AL of the light emitting element LD. For example, the second insulating layer INS2 may include at least one selected from among an organic material and an inorganic material.

The first contact electrode CNE1 and the second contact electrode CNE2 may be arranged on the first insulating layer INS1. The first contact electrode CNE1 may electrically connect the first electrode ELT1 and the light emitting element LD to each other, and the second contact electrode CNE2 may electrically connect the second electrode ELT2 and the light emitting element LD to each other.

In one or more embodiments, the first contact electrode CNE1 may provide an anode signal to the light emitting element LD, and the second contact electrode CNE2 may provide a cathode signal to the light emitting element LD.

The first contact electrode CNE1 and the second contact electrode CNE2 may include a conductive material. For example, the first contact electrode CNE1 and the second contact electrode CNE2 may include a transparent conductive material including Indium Tin Oxide (ITO), Indium Zinc Oxide (IZO), and/or Indium Tin Zinc Oxide (ITZO), but the present disclosure is not limited thereto.

The third insulating layer INS3 may be arranged over the first contact electrode CNE1. The third insulating layer INS3 may include any one (e.g., at least one) of the materials exemplified as the material constituting the first insulating layer INS1. In an example, a portion of the third insulating layer INS3 may be arranged between the first contact electrode CNE1 and the second contact electrode CNE2, to prevent or reduce the first contact electrode CNE1 and the second contact electrode CNE2 from being electrically short-circuited to each other.

The fourth insulating layer INS4 may be arranged over the first contact electrode CNE1, the second contact electrode CNE2, and the third insulating layer INS3. The fourth insulating layer INS4 may protect individual components of the display element layer DPL. For example, the fourth insulating layer INS4 may include at least one selected from among silicon nitride (SiNₓ), silicon oxide (SiOₓ), silicon oxynitride (SiOₓN_{y}), and aluminum oxide (AlOₓ).

In one or more embodiments, the structure of the pixel PXL is not limited to the example described above with reference to FIG. 4, and one or more suitable modifiable embodiments may be implemented.

In one or more embodiments, a planarization layer for cancelling or reducing a step difference of (e.g., between) individual components may be further included. In one or more embodiments, a color conversion layer including a quantum dot configured to change a wavelength of light may be arranged on the display element layer DPL. In accordance with one or more embodiments, a color filter for allowing light having a set or predetermined wavelength to be selectively transmitted therethrough may be further arranged.

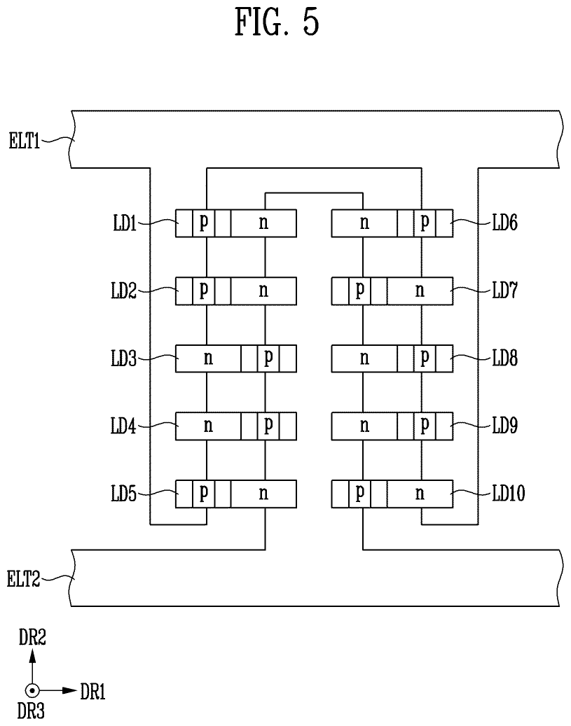

FIG. 5 is a view illustrating in more detail a process in which light emitting elements are aligned on an alignment electrode.

Referring to FIG. 5, after the first electrode ELT1 and the second electrode ELT2 are arranged on the substrate SUB, a plurality of light emitting elements LD1 to LD10 may be aligned between the first electrode ELT1 and the second electrode ELT2.

For example, after the first electrode ELT1 and the second electrode ELT2 are arranged on the substrate SUB to be spaced apart (e.g., separated) from each other, an ink including the plurality of light emitting elements LD1 to LD10 may be provided. After that, an AC voltage having a set or predetermined frequency and a set or predetermined magnitude may be applied between the first electrode ELT1 and the second electrode ELT2. When the AC voltage is applied between the first electrode ELT1 and the second electrode ELT2, polarities of voltages of the first electrode ELT1 and the second electrode ELT2 may be changed as time elapses. The first electrode ELT1 and the second electrode ELT2 may have polarities opposite to each other. For example, when the first electrode ELT1 is a positive electrode, the second electrode ELT2 may be a negative electrode. When the first electrode ELT1 is the negative electrode, and the second electrode ELT2 may be the positive electrode. When the AC voltage is applied between the first electrode ELT1 and the second electrode ELT2, an electric field may be formed between the first electrode ELT1 and the second electrode ELT2. When the electric field is formed between the first electrode ELT1 and the second electrode ELT2, the plurality of light emitting elements LD1 to LD10 may be settled between the first electrode ELT1 and the second electrode ELT2 by a dielectrophoretic force. The dielectrophoretic force may act on an induced dipole within a non-uniform (e.g., substantially non-uniform) electric field. Each of the plurality of light emitting elements LD1 to LD10 may be settled between the first electrode ELT1 and the second electrode ELT2 in a state in which each of the plurality of light emitting elements LD1 to LD10 is biased (e.g., oriented) in the first direction DR1 or the opposite direction of the first direction DR1.

In driving of the display device, some of the plurality of light emitting elements LD1 to LD10 may not normally (e.g., suitably) emit light. For example, as described with reference to FIG. 4, the transistor TR is connected to the first electrode ELT1, and the power line PL is connected to the second electrode ELT2, so that a current flows from the transistor TR to the power line PL via the light emitting element LD in the driving of the display device. Light emitting elements aligned in a forward direction normally or suitably emit light, but light emitting elements aligned in a reverse direction may not normally or suitably emit light. The light emitting elements aligned in the forward direction may be light emitting elements in which a P-type semiconductor is arranged adjacent to an electrode having a relatively high potential among the first and second electrodes ELT1 and ELT2. The light emitting elements aligned in the reverse direction may be light emitting elements in which an N-type semiconductor is arranged adjacent to an electrode having a relatively high potential among the first and second electrodes ELT1 and ELT2. For example, as described with reference to FIG. 4, when the transistor TR is connected to the first electrode ELT1 and the power line PL is connected to the second electrode ELT2, so that a current flows from the transistor TR to the power line PL via the light emitting element LD in the driving of the display device, first, second, fifth, sixth, eighth, and ninth light emitting elements LD1, LD2, LD5, LD6, LD8, and LD9 among the plurality of light emitting elements LD1 to LD10 may normally or suitably emit light, but third, fourth, seventh, and tenth light emitting elements LD3, LD4, LD7, and LD10 may not emit light. Therefore, it is important to align the plurality of light emitting elements LD1 to LD10 such that the plurality of light emitting elements LD1 to LD10 are biased (e.g., oriented) in substantially the same direction, in a process of allowing the plurality of light emitting elements LD1 to LD10 to be settled between the first electrode ELT1 and the second electrode ELT2.

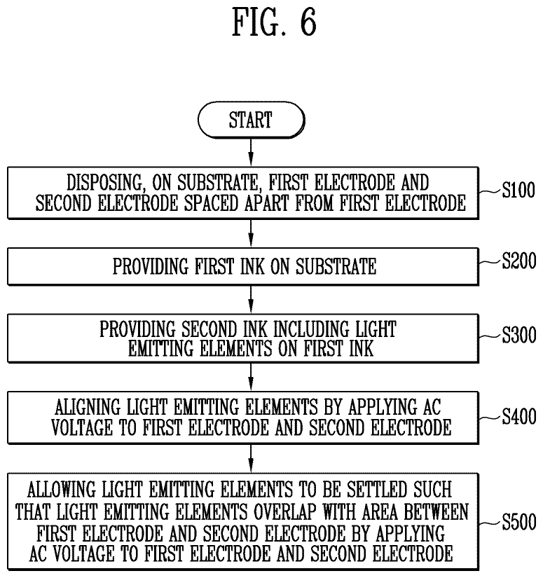

FIG. 6 is a flowchart illustrating a method of manufacturing the display device in accordance with embodiments of the present disclosure.

The method shown in FIG. 6 includes a method of aligning a light emitting element.

Referring to FIG. 6, in the method shown in FIG. 6, a first electrode and a second electrode spaced apart from the first electrode may be arranged on a substrate (S100), a first ink may be provided on the substrate (S200), a second ink including light emitting elements may be provided on the first ink (S300), the light emitting elements may be aligned by applying an AC voltage to the first electrode and the second electrode (S400), and the light emitting elements may be settled to overlap with an area between the first electrode and the second electrode by applying the AC voltage to the first electrode and the second electrode (S500).

Referring to FIGS. 4 and 6, in the step (e.g., act or task) S100, the first electrode ELT1 and the second electrode ELT2 may be provided on the substrate SUB. The substrate SUB may be in a state after the protective layer PSV is arranged on the second interlayer insulating layer ILD2. After the first electrode ELT1 and the second electrode ELT2 are provided on the substrate SUB, the first insulating layer INS1 may be arranged over the first electrode ELT1 and the second electrode ELT2.

In the step (e.g., act or task) S200, a first ink including a solvent may be provided on the substrate SUB on which the first electrode ELT1 and the second electrode ELT2 are provided. For example, the solvent may be a liquid mixture having fluidity.

In the step (e.g., act or task) S300, a second ink including a solvent and a plurality of light emitting elements LD may be provided on the substrate SUB on which the first electrode ELT1 and the second electrode ELT2 are provided. For example, the solvent may be a liquid mixture having fluidity, and the plurality of light emitting elements LD may be provided to be dispersed in the solvent.

In the step (e.g., act or task) S400, an AC voltage may be applied between the first electrode ELT1 and the second electrode ELT2. For example, a ground voltage may be applied to the first electrode ELT1, and the AC voltage may be applied to the second electrode ELT2. The light emitting elements LD may be in a state in which the light emitting elements LD are not immediately settled between the first electrode ELT1 and the second electrode ELT2 due to the first ink but rather are floated in the second ink. In one or more embodiments, the light emitting elements LD may be aligned to be biased (e.g., oriented) in substantially the same direction in a floating state.

In the step (e.g., act or task) S500, the AC voltage may be continuously applied between the first electrode ELT1 and the second electrode ELT2. For example, the ground voltage may be applied to the first electrode ELT1, and the AC voltage may be applied to the second electrode ELT2. In one or more embodiments, the AC voltage may have a set or predetermined frequency. For example, the frequency of the AC voltage may be set such that the AC voltage forms a positive dielectrophoresis. When the AC voltage forms the positive dielectrophoresis, the light emitting elements LD may be settled between the first electrode ELT1 and the second electrode ELT2 by a dielectrophoretic force. For example, the light emitting elements LD may be aligned to be biased (e.g., oriented) in substantially the same direction in the step (e.g., act or task) S400, and may be settled between the first electrode ELT1 and the second electrode ELT2 by the dielectrophoretic force.

FIGS. 7 to 9 are views illustrating an example of a waveform of an AC voltage according to the method shown in FIG. 6.

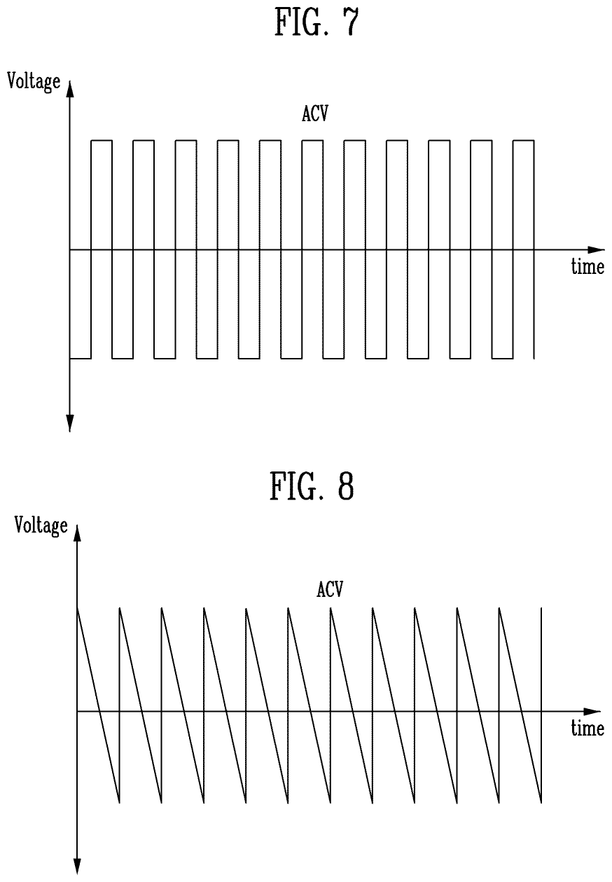

In FIG. 7, it is illustrated that the waveform of an AC voltage ACV is a square wave. In FIG. 8, it is illustrated that the waveform of the AC voltage ACV is a sawtooth wave. However, the waveform of the AC voltage ACV is not limited by embodiments, and may be variously suitably set.

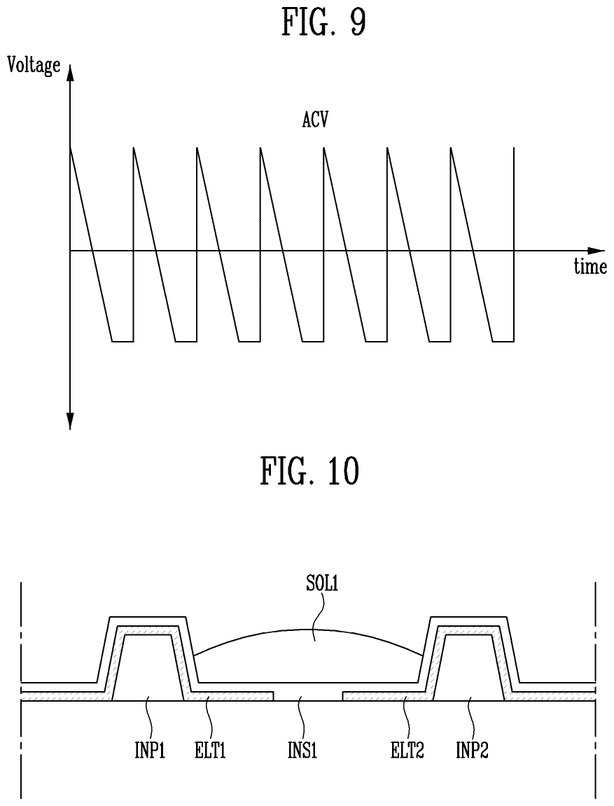

Referring to FIGS. 7 to 9, the waveform of the AC voltage ACV may include at least one selected from among a square wave, a sine wave, a triangle wave, and a sawtooth wave. In one or more embodiments, as shown in FIG. 9, the AC voltage ACV may have an asymmetric waveform. In one or more embodiments, the AC voltage ACV may be a voltage obtained adding a DC offset voltage to the AC voltage ACV. When the AC voltage ACV is an asymmetric waveform, and/or a voltage obtained adding a DC offset voltage to the AC voltage ACV, an asymmetric electric field is formed between the first electrode and the second electrode, so that the deflection factor of the light emitting elements can be further increased.

FIGS. 10 to 13 are views illustrating in more detail a process in which a light emitting element is aligned according to the method shown in FIG. 6.

Referring to FIG. 10, a first ink SOL1 may be provided on the substrate on which the first electrode ELT1 and the second electrode ELT2 are formed. For example, the first ink SOL1 may not include (e.g., may exclude) any light emitting elements.

Referring to FIG. 11, after a second ink SOL2 including light emitting elements LD is provided, the light emitting elements LD may exist in a state in which the light emitting elements LD are randomly dispersed in the second ink SOL2 before an AC voltage is applied. Also, the light emitting elements LD included in the second ink SOL2 may be floated due to the first ink SOL1.

In one or more embodiments, a solvent of the first ink SOL1 and a solvent of the second ink SOL2 may be immiscible. For example, two solvents immiscible with each other selected from among acetic acid, acetone, acetonitrile, benzene, butanol, n-butyl acetate, carbon tetrachloride, chloroform, cyclohexane, 1,2-dichloroethane, dichloromethane, diethyl ether, diisopropyl ether, dimethylformamide, dimethyl sulfoxide (DMSO), dioxane, ethanol, ethyl acetate, heptane, hexane, isooctane, isopropanol, methanol, methyl ethyl ketone (MEK), methyl tert-butyl (MTBE), pentane, 1-propanol, tetrahydrofuran (THF), toluene, trichloroethylene, water, and xylene may be selected as the solvent of the first ink SOL1 and the solvent of the second ink SOL2.

In one or more embodiments, the solvent of the first ink SOL1 may have a density higher than a density of the solvent of the second ink SOL2. For example, two solvents selected from among acetic acid, acetone, acetonitrile, benzene, 1-butanal, 2-butanol, 2-butanone, t-butyl alcohol, carbon tetrachloride, chlorobenzene, chloroform, cyclohexane, 1.2-dichloroethane, diethylene glycol, diethyl ether, diethylene glycol dimethyl ether, 1,2-dimethoxy-ethane, dimethyl-formamide, dimethyl sulfoxide, 1,4-dioxane, ethanol, ethyl acetate, ethylene glycol, glycerin, heptane, hexamethylphosphoramide, hexamethylphosphorous triamide, hexane, methanol, methyl t-butyl ether (MTBE), methylene chloride, N-methyl-2-pyrrolidinone (NMP), nitromethane, pentane, petroleum ether, 1-propanol, 2-propanol, pyridine, tetrahydrofuran (THF), toluene, triethylamine, water, heavy water, o-xylene, m-xylene, and p-xylene may be selected. A solvent having a relatively high (e.g., higher) density may be selected as the solvent of the first ink SOL1 from the selected two solvents, and a solvent having a relatively low (e.g., lower) density may be selected as the solvent of the second ink SOL2 from the selected two solvents.

In one or more embodiments, the solvent of the first ink SOL1 may have a viscosity higher than a viscosity of the solvent of the second ink SOL2. For example, two solvents selected from among acetic acid, acetic anhydride, acetone, acetonitrile, benzene, benzonitrile, 1-butanol, 2-butanone, butyl acetate, tert-butyl methyl ether, carbon disulfide, carbon tetrachloride, chlorobenzene, 1-chlorobutane, chloroform, cyclohexane, cyclopentane, 1,2-dichlorobenzene, 1,2-dichloroethane, dichloromethane, diethylene glycol, diethylether, N,N-dimethylacetamide, N,N-dimethylformamide, 1,4-dioxane, ether, ethyl acetate, ethyl alcohol, ethylene glycol, dimethyl ether, heptane, hexane, 2-methoxyethanol, 2-methaoxyethyl acetate, methyl alcohol, 2-methylbutane, 3-methyl-1-butanol, 4-methyl-2-pentanone, 2-methyl-1-propanol, 2-methy-2-propanol, 1-methyl-2-pyrrolidinone, methyl sulfoxide, nitromethane, 1-octanol, pentane, 3-pentanone, 1-propanol, 2-propanol, propylene carbonate, pyridine, tetrachlororethylene, tetrahydrofuran (THF), toluene, 1,1,2-trichlorotrifluoroethane, 2,2,4-trimethylpentane, water, o-xylene, m-xylene, and p-xylene may be selected. A solvent having a relatively high (e.g., higher) viscosity may be selected as the solvent of the first ink SOL1 from the selected two solvents, and a solvent having a relatively low (e.g., lower) viscosity may be selected as the solvent of the second ink SOL2 from the selected two solvents.

In one or more embodiments, the solvent of the first ink SOL1 may have a surface tension higher than a surface tension of the solvent of the second ink SOL2. For example, two solvents selected from among 1,2-dichloroethane, 1,2,3-tribromopropane, 1,3,5-trimethylbenzene, 1,4-dioxane, 1,5-pentanediol, 1-chlorobutane, 1-decanol, 1-nitropropane, 1-octanol, acetone, aniline, 2-aminoethanol, anthranilic acid ethylester, anthranilic acid methylester, benzene, benzylalcohol, benzyl benzoate (BNBZ), bromobenzene, bromoform, butyronitrile, carbon disulfide, quinoline, chlorobenzene, chloroform, cyclohexane, cyclohexanol, cyclopentanol, p-cymene, decaline, dichloromethane, diiodomethane, 1,3-diiodopropane, diethylene glycol (DEG), dipropylene glycol, dipropylene glycol monomethylether, dodecyl benzene, ethanol, ethylbenzene, ethylbromide, ethylene glycol (EG), formamide (FA), fumaric acid diethylester, furfural, glycerol (GLY), ethylene glycol monoethyl ether, hexachlorobutadiene, iodobenzene, isoamylchloride, isobutylchloride, isopropanol, isopropylbenzene, isovaleronitrile, m-nitrotoluene, mercury, methanol, methyl ethyl ketone (MEK), methyl naphthalene, N,N-dimethyl acetamide (DMA), N,N-dimethyl formamide (DMF), N-methyl-2-pyrrolidone, n-decane (DEC), n-dodecane (DDEC), n-heptane, n-hexadecane (HDE), n-hexane (HEX), n-octane (OCT), n-tetradecane (TDEC), n-undecane, n-butylbenzene, n-propylbenzene, nitroethane, nitrobenzene, nitromethane, o-nitrotoluene, perfluoroheptane, perfluorohexane, perfluorooctane, phenylisothiocyanate, phthalic acid diethylester, polyethylene glycol (PEG), polydimethyl siloxane, propanol, pyridine, 3-pyridylcarbinol (PYC), pyrrole (PY), sym-tetrachloromethane, tetrahydrofuran (THF), thiodiglycol (TDG), toluene, tricresylphosphate (TCP), water, o-xylene, m-xylene, α-bromonaphthalene, and α-chloronaphthalene may be selected. A solvent having a relatively high (e.g., higher) surface tension may be selected as the solvent of the first ink SOL1 from the selected two solvents, and a solvent having a relatively low (e.g., lower) surface tension may be selected as the solvent of the second ink SOL2 from the selected two solvents.

However, the present disclosure is not limited to the solvent of the first ink SOL1 and the solvent of the second ink SOL2.

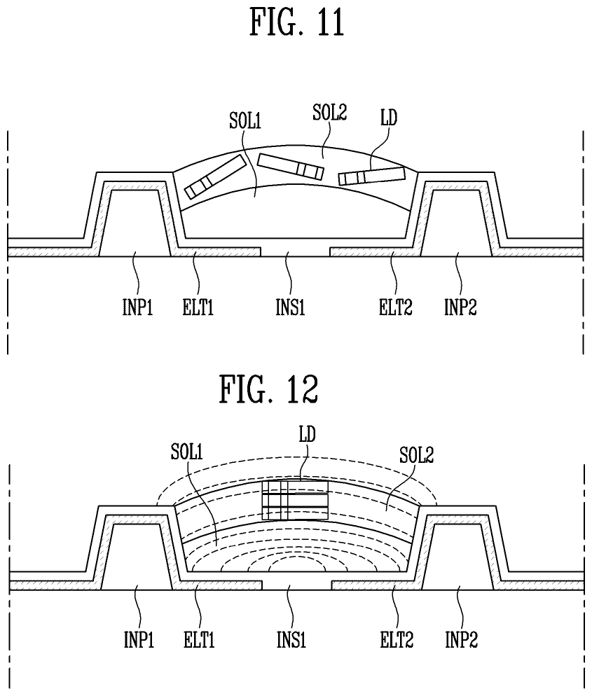

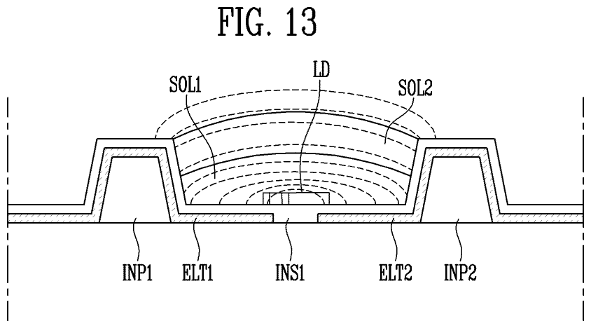

Referring to FIG. 12, the light emitting elements LD may be aligned due to an AC voltage applied to the first electrode ELT1 and the second electrode ELT2. The light emitting elements LD may be aligned in a state in which the light emitting elements LD are floated between the first electrode ELT1 and the second electrode ELT2. In one or more embodiments, by a switching force acting on an intrinsic permanent dipole, the light emitting elements LD may be biased (e.g., oriented) in substantially the same direction in the state in which the light emitting elements LD are floated between the first electrode ELT1 and the second electrode ELT2. The switching force may refer to a force for changing the direction in which the light emitting elements LD are biased to the opposite direction. For example, when the AC voltage is applied for a set or predetermined time in a state in which the light emitting elements LD are floated in the inks SOL1 and SOL2, the light emitting elements LD may act as Induced Quasi-Permanent Dipoles (IQ-PDs) which will be described in more detail herein below. The light emitting elements LD may be biased (e.g., oriented) in substantially the same direction by a switching force acting on the IQ-PDs.

Referring to FIG. 13, the light emitting elements LD may be settled to overlap with an area between the first electrode ELT1 and the second electrode ELT2 due to the AC voltage applied to the first electrode ELT1 and the second electrode ELT2. The AC voltage may form a positive dielectrophoresis. When the positive dielectrophoresis is formed, a dielectrophoretic force may act toward a side at which the density of an electric field is relatively (e.g., comparatively) high. The density of an electric field formed between the first electrode ELT1 and the second electrode ELT2 may be highest in an area adjacent to the first electrode ELT1 and the second electrode ELT2. Therefore, the light emitting elements LD may be settled between the first electrode ELT1 and the second electrode ELT2.

As such, after the light emitting elements LD are biased (e.g., oriented) in substantially the same direction in the state in which the light emitting elements LD are floated, the light emitting elements LD may be settled between the first electrode ELT1 and the second electrode ELT2. Accordingly, the deflection factor of the light emitting elements LD can be increased.

Referring to FIGS. 4 and 13, in one or more embodiments, the solvent of the first ink SOL1 and the solvent of the second ink SOL2 may be volatilized and removed. In one or more embodiments, the second insulating layer INS2 may be arranged on the light emitting elements LD. In one or more embodiments, the second insulating layer INS2 may be arranged in a state in which the solvent of the first ink SOL1 and the solvent of the second ink SOL2 are not removed.

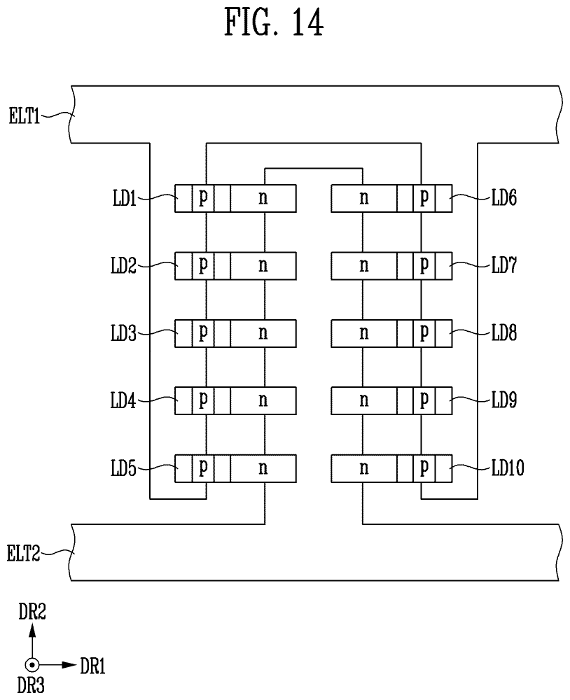

FIG. 14 is a view illustrating an example of the substrate on which light emitting elements are aligned according to the method shown in FIG. 6.

Referring to FIG. 14, the light emitting elements LD1 to LD10 may be aligned in the forward direction to be settled between the first electrode ELT1 and the second electrode ELT2. For example, as shown in FIG. 14, the light emitting elements LD1 to LD10 may be arranged between the first electrode ELT1 and the second electrode ELT2 in a state in which the light emitting elements LD1 to LD10 are aligned such that the P-type semiconductor is adjacent to the first electrode ELT1. For example, as described with reference to FIG. 5, when the transistor TR is connected to the first electrode ELT1 and the power line PL is connected to the second electrode ELT2, so that a current flows from the transistor TR to the power line PL via the light emitting element LD in the driving of the display device, the light emitting elements LD1 to LD10 may all be aligned in the forward direction. Thus, the light emitting elements LD1 to LD10 can normally or suitably emit light.

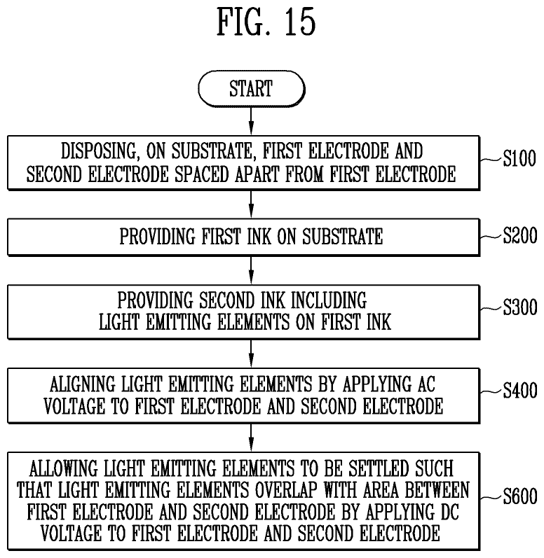

FIG. 15 is a flowchart illustrating a method of manufacturing the display device in accordance with embodiments of the present disclosure.

The method in accordance with these embodiments is configured substantially identical to the method shown in FIG. 6 except step (e.g., act or task) S600. Therefore, components substantially identical or similar to those shown in FIG. 6 are designated by like reference numerals, and overlapping descriptions will not be provided.

Referring to FIG. 15, in the method shown in FIG. 15, a first electrode and a second electrode spaced and/or apart (e.g., spaced apart or separated) from the first electrode may be arranged on a substrate (S100), a first ink may be provided on the substrate (S200), a second ink including light emitting elements may be provided on the first ink (S300), the light emitting elements may be aligned by applying an AC voltage to the first electrode and the second electrode (S400), and the light emitting elements may be settled to overlap with an area between the first electrode and the second electrode by applying a DC voltage to the first electrode and the second electrode (S600).

Referring to FIGS. 4 and 15, in the step (e.g., act or task) S600, a DC voltage may be applied between the first electrode EL1 and the second electrode ELT2. For example, the DC voltage may form a positive dielectrophoresis. When the DC voltage forms the positive dielectrophoresis, the light emitting elements LD may be settled between the first electrode ELT1 and the second electrode ELT2 by a dielectrophoretic force. For example, in the step (e.g., act or task) S400, the light emitting elements LD may be aligned to be biased (e.g., oriented) in substantially the same direction. In the step (e.g., act or task) S600, the light emitting elements LD may be settled between the first electrode ELT1 and the second electrode ELT2 by the dielectrophoretic force.

In one or more embodiments, in the step (e.g., act or task) S600, an AC voltage to which a DC offset voltage is added may be applied between the first electrode ELT1 and the second electrode ELT2. The DC offset voltage may be set to form a positive dielectrophoresis.

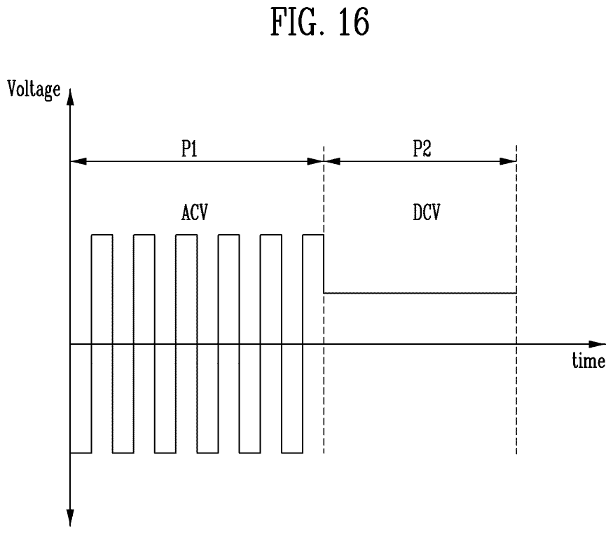

FIG. 16 is a view illustrating an example of a waveform of a voltage applied to the first electrode and the second electrode according to the method shown in FIG. 15.

In FIG. 16, it is illustrated that the waveform of an AC voltage ACV is a square wave. However, the waveform of the AC voltage ACV is not limited by embodiments, and may be variously suitably set.

Referring to FIG. 16, the AC voltage ACV may be applied to the first electrode and the second electrode in a first period P1 in which the light emitting elements are aligned. In one or more embodiments, a DC voltage DCV may be applied to the first electrode and the second electrode in a second period P2 in which the light emitting elements are settled. The DC voltage DCV is applied to the first electrode and the second electrode in the second period, so that the light emitting elements can be settled to overlap with an area between the first electrode and the second electrode.

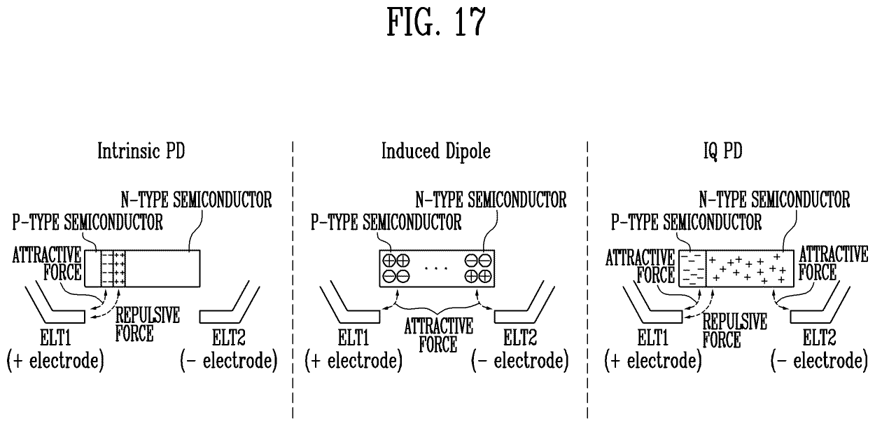

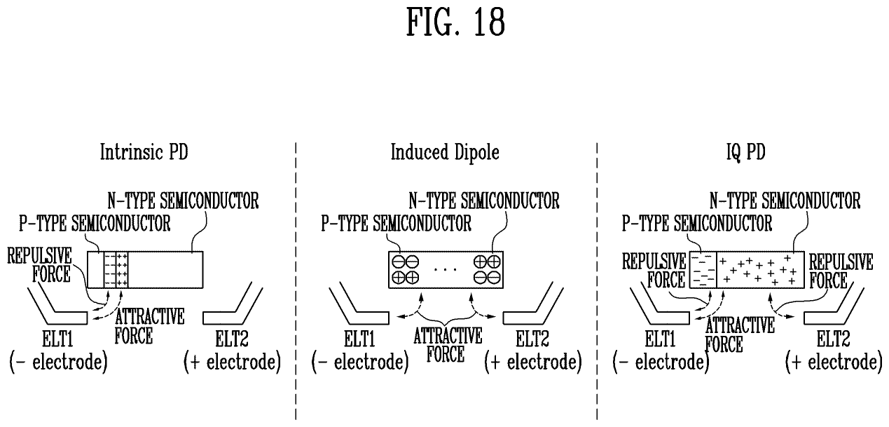

FIGS. 17 and 18 are views illustrating a kind (or kinds) of dipole moment generated in a light emitting element and a force acting on the light emitting element according the kind of dipole moment.

Referring to FIGS. 17 and 18, when an AC voltage is applied between the first electrode ELT1 and the second electrode ELT2, a positive voltage and a negative voltage may be alternately applied between the first electrode ELT1 and the second electrode ELT2. For example, the positive voltage may be applied between the first electrode ELT1 and the second electrode ELT2 during a half cycle, and the negative voltage may be applied between the first electrode ELT1 and the second electrode ELT2 during a next half cycle. The first electrode ELT1 and the second electrode ELT2 may have polarities opposite to each other. For example, FIG. 17 may illustrate a case where the first electrode ELT1 is a positive electrode (+electrode) and the second electrode ELT2 is a negative electrode (−electrode), and FIG. 18 may illustrate a case where the first electrode ELT1 is the negative electrode (−electrode) and the second electrode ELT2 is the positive electrode (+electrode).

In FIGS. 17 and 18, light emitting elements shown at left, middle, and right sides may represent an intrinsic PD, an induced dipole, and an IQ-PD, respectively.

The intrinsic PD may be generated as, in an area in which a P-type semiconductor and an N-type semiconductor of the light emitting element are joined, holes are diffused toward the N-type semiconductor and electrons are diffused toward the P-type semiconductor. In one or more embodiments, a width of the P-type semiconductor of the light emitting element may be narrower than a width of the N-type semiconductor of the light emitting element. Therefore, when the intrinsic PD is arranged as shown in FIGS. 17 and 18, influence given to the intrinsic PD by the first electrode ELT1 as an electrode adjacent to a portion (hereinafter, referred to as a depletion area) at which the P-type semiconductor and the N-type semiconductor are joined may be greater than influence given to the intrinsic PD by the second electrode ELT2. As shown in FIG. 17, an attractive force and a repulsive force may concurrently (e.g., simultaneously) act between the intrinsic PD and the first electrode ELT1. For example, in the depletion area, the attractive force may act between a depletion area in which the P-type semiconductor is formed and the first electrode ELT1, and the repulsive force may act between a depletion area in which the N-type semiconductor is formed and the first electrode ELT1. As shown in FIG. 18, an attractive force and a repulsive force may concurrently (e.g., simultaneously) act between the intrinsic PD and the first electrode ELT1. For example, in the depletion area, the repulsive force may act between a depletion area in which the P-type semiconductor is formed and the first electrode ELT1, and the attractive force may act between a depletion area in which the N-type semiconductor is formed and the first electrode ELT1.

The induced dipole may be generated by an electric field formed at the periphery of the light emitting element. For example, as shown in FIG. 17, when the first electrode ELT1 is a positive electrode and the second electrode ELT2 is a negative electrode, negative charges may be induced in an area adjacent to the first electrode ELT1 of the light emitting element, and positive charges may be induced in an area adjacent to the second electrode ELT2 of the light emitting element. Accordingly, an attractive force may act between the first and second electrodes ELT1 and ELT2 and the induced dipole. As shown in FIG. 18, when the first electrode ELT1 is a negative electrode and the second electrode ELT2 is a positive electrode, positive charges may be induced in an area adjacent to the first electrode ELT1 of the light emitting element, and negative charges may be induced in an area adjacent to the second electrode ELT2 of the light emitting element. Accordingly, an attractive force may act between the first and second electrodes ELT1 and ELT2 and the induced dipole. For example, when the AC voltage is applied between the first electrode ELT1 and the second electrode ELT2, the attractive force may always (e.g., primarily) act on the induced dipole.

The IQ-PD may be generated by an electric field formed at the periphery of the light emitting element. When the electric field is formed at the periphery of the light emitting element, electrons moving from an N-type semiconductor may exist in a P-type semiconductor, and holes moving from the P-type semiconductor may exist in the N-type semiconductor. Accordingly, the IQ-PD may be generated. In one or more embodiments, a width of the P-type semiconductor of the light emitting element may be narrower than a width of the N-type semiconductor of the light emitting element. Therefore, a density of the electrons existing in the P-type semiconductor may be higher than a density of the holes existing in the N-type semiconductor. When the IQ-PD is arranged as shown in FIGS. 17 and 18, influence given to the P-type semiconductor by the first electrode ELT1 may be greater than influence given to the N-type semiconductor by the second electrode ELT2. As shown in FIG. 17, in the IQ-PD, when the first electrode ELT1 is a positive electrode and the second electrode ELT2 is a negative electrode, an attractive force may act between the P-type semiconductor and the first electrode ELT1, and an attractive force may also act between the N-type semiconductor and the second electrode ELT2. The attractive force acting between the P-type semiconductor and the first electrode ELT1 may be greater than the attractive force acting between the N-type semiconductor and the second electrode ELT2. As shown in FIG. 18, in the IQ-PD, when the first electrode ELT1 is a negative electrode and the second electrode ELT2 is a positive electrode, a repulsive force may act between the P-type semiconductor and the first electrode ELT1, and a repulsive force may also act between the N-type semiconductor and the second electrode ELT2. The repulsive force acting between the P-type semiconductor and the first electrode ELT1 may be greater than the repulsive force acting between the N-type semiconductor and the second electrode ELT2.

At a junction portion of the light emitting element, the width of a depletion area in which the intrinsic PD is formed may be relatively (e.g., comparatively) very narrow. Therefore, in FIGS. 17 and 18, magnitudes of the attractive force and the repulsive force, which act between the intrinsic PD and the first electrode ELT1, may be very similar to each other, and hence the attractive force and the repulsive force may be cancelled (e.g., may cancel each other out).

As shown in FIG. 17, when the first electrode ELT1 is a positive electrode and the second electrode ELT2 is a negative electrode, an attractive force may act on the induced dipole and an attractive force may also act on the IQ-PD (e.g., an attractive force may act between the P-type semiconductor and the first electrode ELT1). Therefore, the direction in which the light emitting element faces may not be switched.

As shown in FIG. 18, when the first electrode ELT1 is a negative electrode and the second electrode ELT2 is a positive electrode, an attractive force may act on the induced dipole, and a repulsive force may act on the IQ-PD (e.g., a repulsive force may act between the P-type semiconductor and the first electrode ELT1). When a magnitude of the repulsive force acting on the IQ-PD is greater than a magnitude of the attractive force acting on the induced dipole, the direction in which the light emitting element faces may be switched.

The magnitude of the attractive force acting on the induced dipole may become larger as the distance between the induced dipole and an electrode becomes shorter. Therefore, when the light emitting element is settled between the first electrode ELT1 and the second electrode ELT2, it may be difficult to switch the direction in which the light emitting element faces. The magnitude of the attractive force acting on the induced dipole may become smaller as the distance between the induced dipole and an electrode becomes longer. Therefore, when the light emitting element is in the floating state, the direction in which the light emitting element faces may be readily switched.

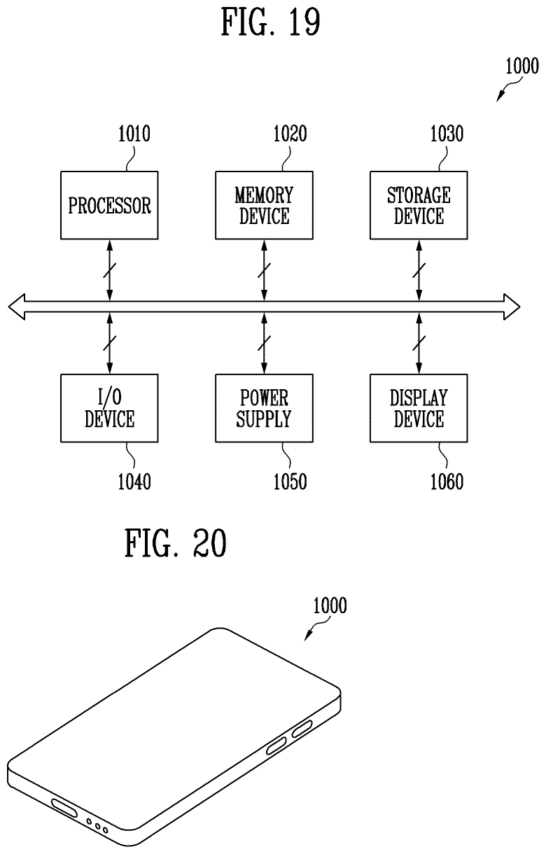

FIG. 19 is a block diagram illustrating an electronic device in accordance with embodiments of the present disclosure. FIG. 20 is a view illustrating an example in which the electronic device shown in FIG. 19 is implemented as a smartphone.

Referring to FIGS. 19 and 20, the electronic device 1000 may include a processor 1010, a memory device 1020, a storage device 1030, an input/output (I/O) device 1040, a power supply 1050, and a display device 1060. The display device 1060 may be the display device shown in FIG. 3. In some embodiments, the electronic device 1000 may further include several ports capable of communicating with a video card, a sound card, a memory card, a USB device, and/or the like, and/or communicating with other systems. In one or more embodiments, as shown in FIG. 20, the electronic device 1000 may be implemented as a smartphone. However, this is merely illustrative, and the electronic device 1000 is not limited thereto. For example, the electronic device 1000 may be implemented as a mobile phone, a video phone, a smart pad, a smart watch, a tablet PC, a vehicle navigation system, a computer monitor, a notebook computer, a head mounted display device, and/or the like.

The processor 1010 may perform specific or set calculations and/or tasks. In one or more embodiments, the processor 1010 may be a microprocessor, a central processing unit, an application processor, and/or the like. The processor 1010 may be connected to other components through an address bus, a control bus, a data bus, and/or the like. In one or more embodiments, the processor 1010 may be connected to an extension bus such as a peripheral component interconnect (PCI) bus.

The memory device 1020 may store data necessary or suitable for an operation of the electronic device 1000. For example, the memory device 1020 may include a nonvolatile memory device such as an Erasable Programmable Read-Only Memory (EPROM) device, an Electrically Erasable Programmable Read-Only Memory (EEPROM) device, a flash memory device, a Phase Change Random Access Memory (PRAM) device, a Resistance Random Access Memory (RRAM) device, a Nano Floating Gate Memory (NFGM) device, a Polymer Random Access Memory (PoRAM) device, a Magnetic Random Access Memory (MRAM) device, and/or a Ferroelectric Random Access Memory (FRAM) device; and/or a volatile memory device such as a Dynamic Random Access Memory (DRAM) device, a Static Random Access Memory (SRAM) device, and/or a mobile DRAM device.

The storage device 1030 may include a Solid State Drive (SSD), a Hard Disk Drive (HDD), a CD-ROM, and/or the like.

The I/O device 1040 may include an input means (e.g., an input element) such as a keyboard, a keypad, a touch screen, and/or a mouse, and an output means (e.g., an output element) such as a speaker and/or a printer. In one or more embodiments, the display device 1060 may be included in the I/O device 1040.

The power supply 1050 may supply power necessary or suitable for an operation of the electronic device 1000. For example, the power supply 1050 may be a power management integrated circuit (PMIC).

The display device 1060 may display an image corresponding to visual information of the electronic device 1000. The display device 1060 may be an organic light emitting display device and/or a quantum dot light emitting display device, but the present disclosure is not limited thereto. The display device 1060 may be connected to other components through the buses and/or another communication link.

The present disclosure can be applied to display devices and electronic devices including the same. For example, the present disclosure can be applied to digital TVs, 3D TVs, mobile phones, smart phones, tablet computers, VR devices, PCs, home appliances, notebook computers, PDAs, PMPs, digital cameras, music players, portable game consoles, navigation systems, and/or the like.

In the method of aligning the light emitting element in accordance with the present disclosure, a first ink is provided before a second ink that includes light emitting elements is provided, so that the light emitting elements can be aligned in a state in which the light emitting elements are floated. Accordingly, the deflection factor of the light emitting elements can be increased.

Example embodiments have been disclosed herein, and although specific terms are employed, they are utilized and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be utilized singly or in combination with features, characteristics, and/or elements described in connection with one or more embodiments unless otherwise specifically indicated. Accordingly, it will be understood by those of skill in the art that one or more suitable changes in form and details may be made without departing from the spirit and scope of the present disclosure as set forth in the following claims and equivalents thereof.

What is claimed is:

1. A method of aligning a light emitting element, the method comprising:
providing a first ink on a substrate on which a first electrode and a second electrode spaced from the first electrode are provided;
providing a second ink comprising light emitting elements on the first ink; and
applying an AC voltage to the first electrode and the second electrode.

2. The method of claim 1, wherein a solvent of the first ink and a solvent of the second ink are immiscible.

3. The method of claim 1, wherein a solvent of the first ink has a density higher than a density of a solvent of the second ink.

4. The method of claim 1, wherein a solvent of the first ink has a viscosity higher than a viscosity of a solvent of the second ink.

5. The method of claim 1, wherein a solvent of the first ink has a surface tension higher than a surface tension of a solvent of the second ink.

6. The method of claim 1, wherein each of the light emitting elements comprises a first conductivity type semiconductor and a second conductivity type semiconductor,
wherein the first conductivity type semiconductor of each of the light emitting elements is to face in a first electrode direction by applying the AC voltage, and
wherein the second conductivity type semiconductor of each of the light emitting elements is to face in a second electrode direction by applying the AC voltage.

7. The method of claim 1, wherein the AC voltage is to form a positive dielectrophoresis.

8. The method of claim 1, wherein the AC voltage has an asymmetric waveform.

9. The method of claim 1, wherein each of waveforms of the AC voltage comprises at least one selected from among a square wave, a sine wave, a triangle wave, and a sawtooth wave.

10. A method of manufacturing a display device, the method comprising:
providing, on a substrate, a first electrode and a second electrode spaced from the first electrode;
providing a first ink on the substrate;
providing a second ink comprising light emitting elements on the first ink; and
aligning the light emitting elements by applying an AC voltage to the first electrode and the second electrode.

11. The method of claim 10, further comprising allowing the light emitting elements to be settled such that the light emitting elements overlap with an area between the first electrode and the second electrode by applying the AC voltage to the first electrode and the second electrode.

12. The method of claim 10, further comprising allowing the light emitting elements to be settled such that the light emitting elements overlap with an area between the first electrode and the second electrode by applying a DC voltage to the first electrode and the second electrode.

13. The method of claim 10, further comprising volatilizing and removing a solvent of the first ink and a solvent of the second ink.

14. The method of claim 10, wherein a solvent of the first ink and a solvent of the second ink are immiscible.

15. The method of claim 10, wherein a solvent of the first ink has a density higher than a density of a solvent of the second ink.

16. The method of claim 10, wherein a solvent of the first ink has a viscosity higher than a viscosity of a solvent of the second ink.

17. The method of claim 10, wherein a solvent of the first ink has a surface tension higher than a surface tension of a solvent of the second ink.

18. The method of claim 10, wherein the AC voltage is to form a positive dielectrophoresis.

19. The method of claim 10, wherein the AC voltage has an asymmetric waveform.

20. The method of claim 10, wherein each of waveforms of the AC voltage comprises at least one selected from among a square wave, a sine wave, a triangle wave, and a sawtooth wave.
